(19) United States
(12) Patent Application Publication
(10) Pub. No.: US 2022/0130641 A1
(43) Pub. Date: Apr. 28, 2022

(54) METHOD OF PRODUCING IONS AND APPARATUS

(71) Applicant: EVATEC AG, Trübbach (CH)

(72) Inventors: Silvio Gees, Bad Ragaz (CH); Edmund Schüngel, Buchs (CH); Manuel Baselgia, Chur (CH)

(21) Appl. No.: 17/428,414

(22) PCT Filed: Feb. 4, 2020
(86) PCT No.: PCT/EP2020/052760

§ 371 Date: Aug. 4, 2021

(30) Foreign Application Priority Data
Feb. 6, 2019 (CH) 00137/19

(51) Int. Cl. H01J 37/32; H01J 37/34; C23C 14/34

(52) U.S. Cl. CPC H01J 37/32091; H01J 37/32449; H01J 37/32357; H01J 2237/332; H01J 37/32568; H01J 37/345; C23C 14/34; H01J 37/32541

(57) ABSTRACT

A method of producing hydrogen ions includes generating a diode-type HF plasma PL. This allows to set or adjust the energy of ions output by the plasma source in an improved manner.

It is one object of the present invention to provide a method of plasma generating ions of a gas species by which the ability of setting or adjusting the energy of the generated ions of the gas species, thereby maintaining plasma stability, is improved.

This is achieved by a method of producing ions of a gas species, comprising
Feeding a gas comprising more than 50% of a gas species into a vacuum space;
establishing in the vacuum space an atmosphere of the gas;
Establishing in the atmosphere a capacitively coupled HF plasma and
Providing a plasma outlet opening arrangement from the vacuum space.

In opposition to generating methods for ions of a gas species at which plasmas are differently realized e.g. by inductive coupling, making use of a capacitively coupled plasma significantly improves the ability as addressed.

The method according to the invention possibly in one or more than one variants thereof, as will be addressed below, may be directly applied to surface treat substrates with or without pre-applied layers, in that the surface of such substrates is exclusively exposed to the plasma outlet opening or may be applied to such substrate in the frame of improving a vacuum layer deposition process for the addressed substrate.

### Definitions:

We understand throughout the present description and claims under a “capacitively coupled plasma” a plasma which is generated between two spaced apart electrodes and is supplied from electric power applied to these to electrodes. Additional electrodes may be provided to influence the plasma.
We understand throughout the present description and claims under HF (high frequency) a frequency f for which there is valid:

1 Mhz≤f≤100 Mhz
We understand throughout the present description under “consisting” of something, that nothing else than the addressed “something” is present.
We understand throughout the present description under “comprising” something, that additional members or steps to the addressed “something” may be present.
We understand throughout the present description under “plasma source” an arrangement that generates and outputs the components of a plasma, i.e. electrons, ions, atoms, neutral molecules.

Whereas the inventors developed the method according to the present first with the addressed gas species being hydrogen, significant advantageous of the addressed method where found by the inventors also when operating the method with gas species different from hydrogen.

Thus, in one variant of the method according to the present invention, the gas species is hydrogen and in a further variant of the method according to the invention, the gas species is oxygen.

In one variant of the method according to the invention the gas comprises at least 80% of the gas species or at least 95% of the gas species or consists of the gas species. Clearly and in the latter case negligible amounts of impurity gases may in practice be present.

One variant of the method according to the invention comprises generating the capacitively coupled plasma exclusively between two electrodes, a first electrode having a larger electrode surface and a second electrode having a smaller electrode surface in the vacuum recipient.

Please note, that one or more than one additional electrode might be provided downstream the plasma outlet opening arrangement, e.g. one or more than one grid, operated on selected electric potential so as to interact in a desired fashion with charged particles leaving the plasma by the outlet opening arrangement.

In one variant of the method according to the invention the plasma outlet opening arrangement is realized by a grid forming at least a part of the smaller electrode surface.

### Definition:

We often address in the present description and claims an arrangement of electrodes in a HF plasma generator in which the plasma is exclusively generated between two electrode surfaces and no further electrode surface influences the plasma as a diode arrangement or, respectively as a diode generated plasma.
When we address throughout the present description and claims an “electrode surface” we mean that surface of an electrode body which is exposed to the plasma i.e. that surface of an electrode body along which a plasma may burn at the respective pressure the plasma source or method is operated or is intended to be operated.

Making use of a diode-generated plasma opens the possibility to pre-set or in situ adjust the energy of the ions of the gas species leaving the plasma outlet opening arrangement e.g. realized by the grid, by varying the plasma DC self-bias potential which may e.g. be performed by acting on the effective extent of one or of both electrode surfaces or in a manner as will be addressed later.

In one variant of the just addressed variants one of the two electrodes is operated on an electric reference DC potential and thus the other electrode is operated on an electric potential including a HF potential.

In one variant of the variant as just addressed, the one electrode is operated on electric ground potential.

Thereby and in one variant the second electrode is operated on the electric reference DC potential.

One variant of method according to the invention comprises generating the capacitively coupled plasma exclusively between two electrodes, a first electrode having a larger electrode surface and a second electrode having a smaller electrode surface and realizing the plasma outlet opening arrangement by a grid forming at least a part of the smaller electrode surface of the second electrode and confining a space on that side of the grid which is located opposite to the larger electrode surface of the first electrode by a shield-frame.

In one variant of the method according to the invention the addressed shield-frame has a metal surface which is operated on the electric potential of the second electrode as a part of the smaller electrode surface.

The etching rate of the smaller electrode surface and thus of the grid surface may be lowered, because at least a part of the metal surface of the addressed shield-frame becomes a part of the smaller electrode surface and enlarges such surface which, solely defined by the grid, might be too small.

One variant of the method according to the invention comprises at least one of pre-setting the energy of ions of the gas species output through said plasma outlet opening arrangement and of in situ adjusting the energy of ions of the gas species output through the plasma outlet opening arrangement.

One variant of the just addressed variant of the method according to the invention comprises in situ adjusting the energy of the ions of the gas species output through the plasma outlet opening arrangement by negative feedback control.

One variant of the method according to the invention comprises generating the capacitively coupled plasma exclusively between two electrodes, a first electrode having a larger electrode surface and a second electrode having a smaller electrode surface and realizing the plasma outlet opening arrangement by a grid forming at least a part of the smaller electrode surface and having a transparency larger than 50%.

As addressed above, a second or even a third grid may be used to increase the ion energy, downstream the one grid forming the outlet opening arrangement, so as to control the ion energy in a desired bandwidth. At least one of these additional grids may be connected to a respective electric potential supply.

Definitions:
We understand throughout the present description and claims under the term “pre-setting the ion energy” that this energy is established on a desired value for long time operation of the plasma source.
We understand throughout the present description and claims under the term “in situ adjusting the ion energy” that this energy is varied during operation of the source. Such adjusting may comprise varying the addressed energy with respect to a pre-set energy level, latter exploited as a working point. Further and if the in situ adjusting is performed by negative feedback control, the preset ion energy may become the desired energy value in the negative feedback control loop.
We understand throughout the present description and claims under the term “energy of ions leaving the plasma outlet opening arrangement” the energy of these ions averaged over the surface of the plasma outlet opening arrangement.

One variant of the method according to the invention comprises generating the capacitively coupled plasma exclusively between two electrodes, a first electrode having a larger electrode surface and a second electrode having a smaller electrode surface and realizing the plasma outlet opening arrangement by a grid forming at least a part of the smaller electrode surface wherein at least a part of the openings of the grid are dimensioned to allow a fraction of the plasma to penetrate therethrough and on that side of the grid opposite the larger electrode surface.

One variant of the method according to the invention comprises generating the capacitively coupled plasma exclusively between two electrodes, a first electrode having a larger electrode surface and a second electrode having a smaller electrode surface and further comprises at least one of pre-setting the energy of ions of the gas species, output through the plasma outlet opening arrangement and of in situ adjusting the energy of the ions of the gas species, output through the plasma outlet opening arrangement, wherein the pre-setting and/or the in situ adjusting is performed by pre-setting and/or in situ adjusting the DC self-bias potential of the HF plasma with respect to the electric DC potential applied to one of the two electrodes.

One variant of the variant as just addressed of the method according to the invention comprises in situ adjusting the energy by negative feedback control.

One variant of the variants as just addressed of the method according to the invention comprises exploiting the electric DC potential difference between the two electrodes as indicative for the DC self-bias potential.

In one variant of the method according to the invention the DC self-bias potential is pre-set and/or in situ adjusted by means of pre-setting and/or of in situ adjusting a magnetic field in the plasma.

One variant of the method according to the invention as just addressed comprises generating the capacitively coupled plasma exclusively between two electrodes, a first electrode having a larger electrode surface and a second electrode having a smaller electrode surface and generating the magnetic field by means of a DC current supplied coil arrangement along a part of the larger electrode surface.

In one variant of the just addressed variant of the method according to the invention, the magnetic field is generated by superimposing the magnetic fields of at least two DC supplied coils.

In one variant of the just addressed variant of the method according to the invention, the magnetic fields of the at least two coils are pre-settable and/or adjustable mutually independently from one another.

Thereby the magnetic field resulting from superimposing may be set or adjusted with respect to its strengths and shape and direction.

One variant of one of the just addressed variants of the method according to the invention comprises pre-setting and/or in situ adjusting the energy of ions of the gas species output from the plasma outlet opening arrangement by presetting and/or in situ adjusting at least one of the absolute value and of direction of at least one of the superimposed magnetic fields and of mutual direction of the at least two superimposed magnetic fields.

One variant of the method according to the invention comprises generating the capacitively coupled plasma exclusively between two electrodes, a first electrode having a larger electrode surface and a second electrode having a smaller electrode surface and operating the smaller electrode surface on a reference DC potential, especially on ground potential, electrically HF supplying the larger electrode surface via a matchbox, thereby capacitively coupling a HF generator to the larger electrode surface, and sensing the DC output bias of the matchbox as indication of the DC self-bias potential.

One variant of the method according to the invention generically comprises negative feedback controlling the energy of ions of the gas species output through the plasma outlet opening arrangement.

One variant of the just addressed variant of the method according to the invention comprises generating the capacitively coupled plasma exclusively between two electrodes, a first electrode having a larger electrode surface and a second electrode having a smaller electrode surface and
operating the smaller electrode surface on ground potential;
supplying the larger electrode surface via a matchbox thereby capacitively coupling a HF generator to the larger electrode surface;
generating a magnetic field by means of a DC current supplied coil arrangement along a part of the larger electrode surface;
sensing the DC output bias of the matchbox;
comparing the sensed DC output bias with a desired value, and
adjusting the magnetic field as a function of a result of said comparing.

The present invention is further directed on a method of vacuum-process coating a substrate or of manufacturing a vacuum-process coated substrate comprising operating the method of producing of ions of a gas species according to the invention and as addressed above possibly with one or more than one of the variants thereof and first-treating the substrate by a process, comprising exposing a surface of the substrate to the plasma outlet opening arrangement and second-treating said surface of said substrate, during and/or before and/or after said first treating, by a vacuum coating process.

In one variant of the method according to the invention and as just addressed, the first-treating step—or one of the first-treating steps—consists exclusively of exposing the surface of the substrate to the plasma outlet opening arrangement. Thus, the method of plasma generating ions is exploited to treat an existing material surface by a plasma source for a distinct plasma treatment.

Thus, during a first treating step and this variant of the method of vacuum-process coating a substrate or of manufacturing a vacuum-process coated substrate the substrate is exclusively exposed to the ions and possibly to fractions of the plasma generated by the method of producing ions of the gas species.

Please note that more than one first-treating step may be performed, e.g. an additional one simultaneously with the second treating step.

The substrate treated by the method of vacuum-process coating a substrate or of manufacturing a vacuum-process coated substrate according to the invention may comprise none, one or more than one layers already before undergoing the addressed method.

One variant of the method just addressed and according to the invention comprises locally moving the substrate from the first-treating to the second-treating or inversely.

One variant of the method just addressed and according to the invention comprises locally moving the substrate from the first-treating directly to the second-treating or inversely.

One variant of the method of vacuum-process coating a substrate or of manufacturing a vacuum-process coated substrate according to the invention comprises performing the first and the second treatings in a common vacuum.

In one variant of the methods of vacuum-process coating a substrate or of manufacturing a vacuum-process coated substrate according to the invention the second-treating comprises or consists of sputter coating the surface of the substrate.

In one variant of the methods of vacuum-process coating a substrate or of manufacturing a vacuum-process coated substrate according to the invention the gas species is hydrogen and the second-treating comprises or consists of coating the substrate with a layer of hydrogenated silicon.

In one variant of the methods of vacuum-process coating a substrate or of manufacturing a vacuum-process coated substrate according to the invention the gas species is hydrogen and the at least one substrate is directly conveyed from the second-treating to the first-treating or inversely, whereby the second-treating is silicon sputter deposition remote from the first treating.

One variant of the methods of vacuum-process coating a substrate or of manufacturing a vacuum-process coated substrate according to the invention comprises maintaining generating ions of the gas species and operation of a source performing the second-treating ongoingly during subsequent treatings of at least two of said substrates.

One variant of the methods of vacuum-process coating a substrate or of manufacturing a vacuum-process coated substrate according to the invention comprises conveying the at least one substrate from the second-treating to the first-treating or inversely, in a vacuum transport chamber and exposing the at least one substrate to the first-treating and to the second-treating located in the transport chamber.

One variant of the methods of vacuum-process coating a substrate or of manufacturing a vacuum-process coated substrate according to the invention, wherein the gas species is hydrogen and the second treating is silicon sputter deposition, comprises depositing a layer thickness D by one cycle of the silicon sputter deposition and, directly subsequently, of hydrogen ion impact by the first treating, for which there is valid:

0.1 nm≤D≤3 nm.

In one variant of the methods of vacuum-process coating a substrate or of manufacturing a vacuum-process coated substrate according to the invention the second-treating is silicon sputter deposition and the silicon sputter deposition is operated in a gas atmosphere comprising more than 50% or more than 80% or more than 95% noble gas or consisting of noble gas.

In one variant of the methods of vacuum-process coating a substrate or of manufacturing a vacuum-process coated substrate according to the invention substrates are conveyed on a circular path, pass the first and the second treatings.

One variant of the just addressed variant of the methods of vacuum-process coating a substrate or of manufacturing a vacuum-process coated substrate according to the invention coating a substrate comprises rotating the substrates around respective substrate central axes.

As was addressed above, departing from recognitions by the inventors when operating the method of producing ions of a gas species with hydrogen as the gas species and for manufacturing substrates with a sputter deposited layer of hydrogenated silicon according to the invention, possibly in one or more than one variants thereof, additional applications of the addressed method of producing ions where found.

Thus the invention is further directed to a method of controlling stress in a layer of a compound material MR or of manufacturing a substrate with a layer, wherein M is sputter deposited and a chemical element R is added at least to a substantial amount by exposing the sputter deposited material to the impact of ions of said element as gas species, which comprises generating the ions by means of a method of producing ions of a gas species and possibly one or more than one of the variants thereof according to the invention.

In one variant of the stress controlling method, the stress is controlled by the method according to one of appendant claims 16 to 26.

Further the present invention is directed to a method of controlling surface roughness of a layer or of manufacturing a substrate with a layer of a compound material MR wherein M is sputter deposited and a chemical element R is added at least to a substantial amount by exposing the sputter deposited material to the impact of ions of said element as the gas species, which comprises generating the ions by means of a method of producing ions of a gas species and possibly one or more than one of the variants thereof, according to the invention.

In one variant of the roughness controlling method, the roughness is controlled by the method according to one of claims 16 to 26.

Still further the present invention is directed to a method of etching a substrate or of manufacturing an etched substrate, comprising generating etching ions by means of the method of producing ions of a gas species and possibly one or more than one of the variants thereof, according to the invention thereby selecting a noble gas as gas species and exposing the substrate to said plasma outlet opening arrangement.

In one variant of the etching method, the energy of etching ions is controlled by the method according to one of claims 16 to 26.

Please note that all variants of the methods according to the invention may be combined unless being contradictory or not practicable.

The present invention is further directed on a plasma source adapted to perform the method of producing ions of a gas species according to the invention or of one or more than one of its variants, is further directed on an apparatus with a plasma source as just addressed adapted to perform the vacuum coating method according to the invention or of one or more than one variants thereof, is further directed on apparatus adapted to perform at least one of the method of controlling stress and of the method of controlling surface roughness, according to the invention, and is further directed to an etching station adapted to perform the etching method according to the invention.

Further the present invention is directed on a plasma source comprising exclusively a first and a second capacitively coupled plasma generating electrode, the first electrode having a larger electrode surface and a second electrode having a smaller electrode surface in a vacuum recipient, a plasma outlet opening arrangement and a gas feed from a gas tank arrangement containing a gas predominantly of a gas species.

In one embodiment of the plasma source according to the invention the plasma outlet opening arrangement is through the second electrode.

In one embodiment of the plasma source according to the invention the second electrode comprises at least one grid. Thereby, and in one embodiment, the grid has a transparency of more than 50%.

In one embodiment of the plasma source according to the invention the second electrode is electrically set on a DC reference potential. Thereby, and in one embodiment the reference potential is ground potential.

One embodiment of the plasma source according to the invention comprises one of the two electrodes set on an electric DC reference potential and a sensing arrangement for the DC bias potential of the other electrode.

In one embodiment of the just addressed embodiment of the plasma source according to the invention the second electrode is set on said DC reference potential.

In one embodiment of the plasma source according to the invention at least one of the larger and of the smaller electrode surfaces is variable.

One embodiment of the plasma source according to the invention comprises a coil arrangement generating a magnetic field in the space between the first and the second electrodes.

In one embodiment of the plasma source according to the invention the first electrode is cup shaped, the inner surface of the cup shaped electrode facing the second electrode.

One embodiment of the plasma source according to the invention comprises a coil arrangement along the outer surface of the cup shaped first electrode generating a magnetic field with predominant directional component towards or from the second electrode in the space between said first and second electrodes.

In one embodiment of the embodiment just addressed of the plasma source according to the invention the coil arrangement comprises at least two coils, independently supplied by respective DC current sources.

One embodiment of the plasma source according to the invention comprises:
the second electrode set on a DC reference potential;
a sensing arrangement with a first output for a signal indicative of the DC bias potential of the first electrode;
a presetting unit with a second output;
a comparing unit with a first input operationally connected to the first output and with a second input operationally connected to the second output and with a third output operationally acting on the plasma potential of a plasma between the first and the second electrodes.

In one embodiment of the embodiment just addressed of the plasma source according to the invention the third output is operationally connected to an electric supply of a coil arrangement generating a magnetic field in a space between the first and the second electrodes.

One embodiment of the plasma source according to the invention, comprises a matchbox with an output arrangement supplying said first electrode with a supply signal comprising a HF signal and outputting a DC component of said supply signal, indicative of said DC bias potential.

In one embodiment of the plasma source according to the invention, the gas species is hydrogen.

An apparatus for vacuum treating substrates according to the present invention comprises a plasma source according to the invention or one or more than one of the embodiments thereof and a further vacuum treatment chamber.

In one embodiment of the apparatus just addressed and according to the invention the plasma source is remote from the further vacuum treatment chamber and a substrate conveyer is provided conveying at least one substrate from the plasma source to the further vacuum treatment chamber or inversely.

In one embodiment of the apparatus according to the invention the gas species of the plasma source is hydrogen and the further vacuum treatment is sputter deposition of silicon.

Two or more than two embodiments of the apparatus according to the invention may be combined unless contractionary or not practicable.

The invention under all the aspects shall now be further exemplified with the help of figures. The figures show:

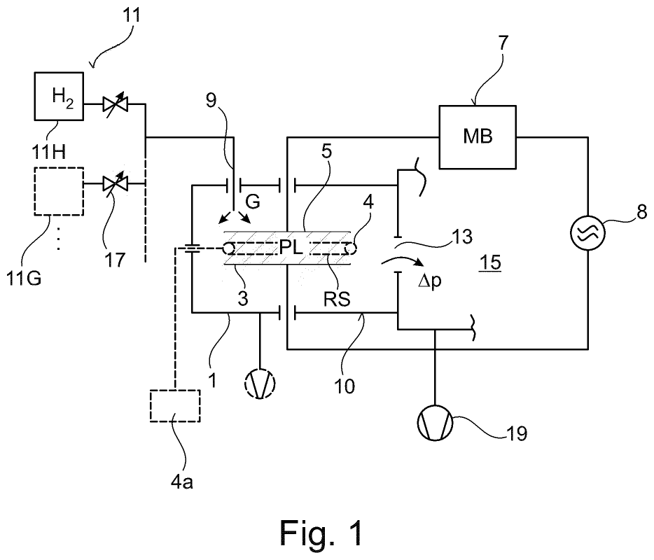

FIG. 1: most schematically and simplified, a generic embodiment of a plasma source performing a variant of the method of producing ions according to the present invention;

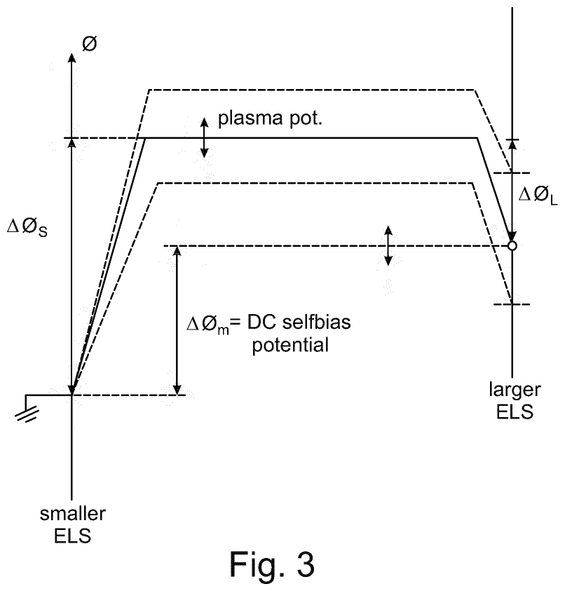

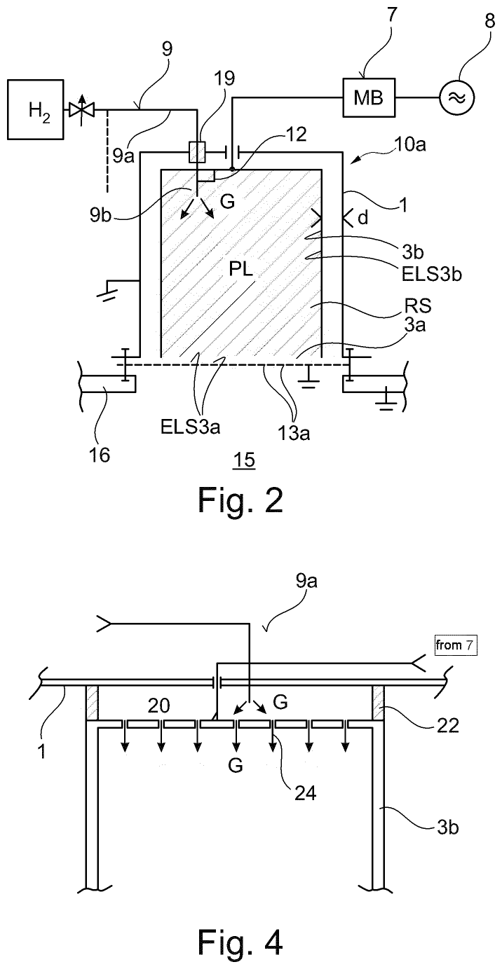

FIG. 2: most schematically and simplified, an embodiment of a plasma source performing a variant of the method of producing ions according to the present invention in which a diode-type generated plasma is used;

FIG. 3: a qualitative, heuristic representation of the electric potentials across a diode-generated plasma;

FIG. 4: schematically and simplified an embodiment of a gas feed to a diode type electrode arrangement as of FIG. 2;

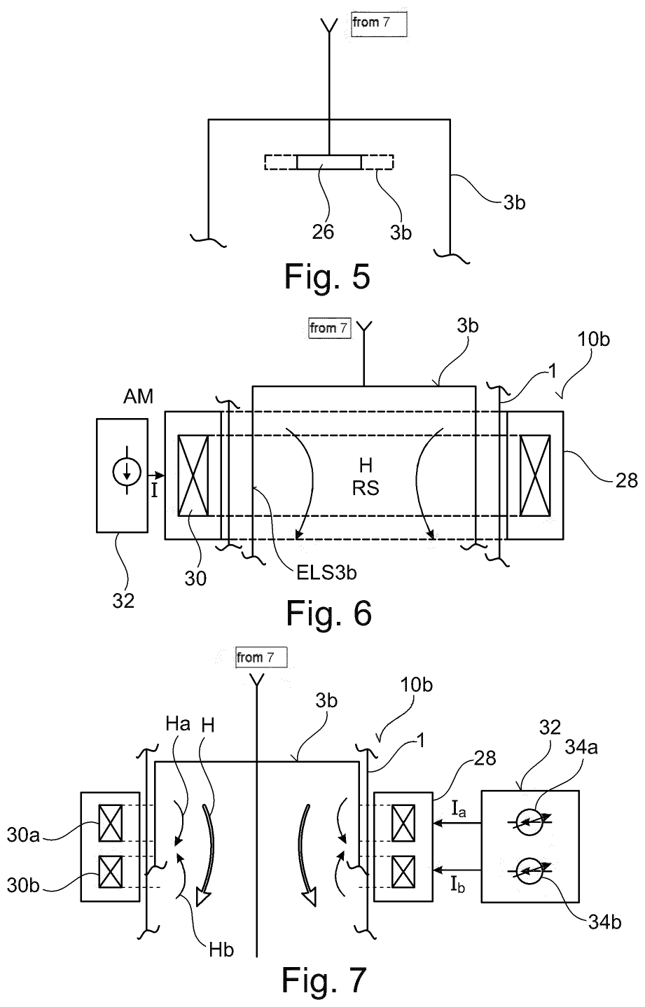

FIG. 5: Schematically and simplified one mode of varying an electrode surface in the plasma source making use of a diode electrode arrangement, as of one of FIGS. 2 to 4;

FIG. 6: most schematically and simplified, a part of a diode type embodiment of a plasma source performing a variant of the method of producing ions according to the present invention constructed for the ability of setting or in situ adjusting the energy of ions leaving the plasma source;

FIG. 7: most schematically and simplified, a part of an embodiment of the embodiment of FIG. 6 operating a variant of the method of producing ions, according to the invention.

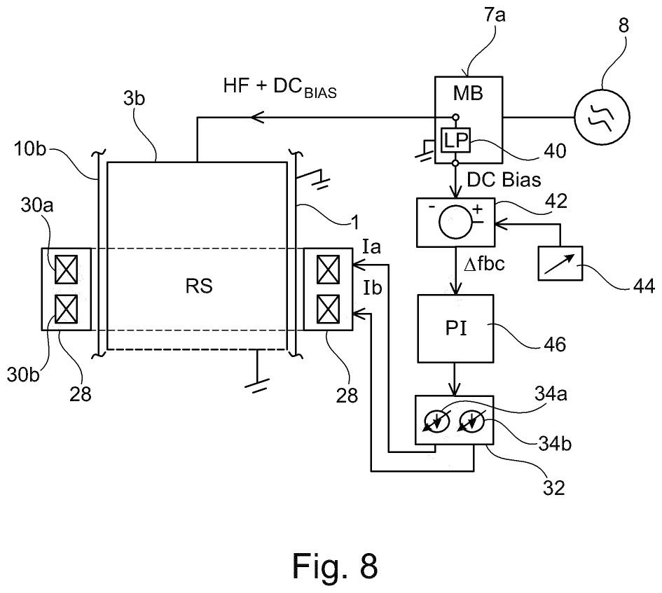

FIG. 8: most schematically and simplified, a part of an embodiment of the embodiments of FIG. 6 or 7 wherein the ion energy is negative feedback controlled.

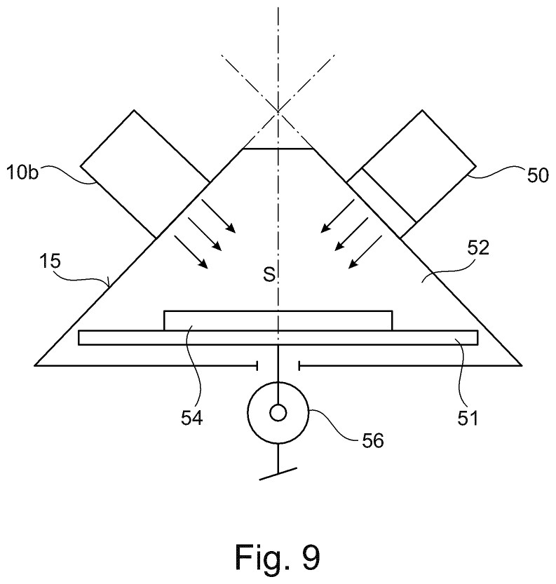

FIG. 9: most schematically and simplified, an embodiment of an apparatus according to the invention;

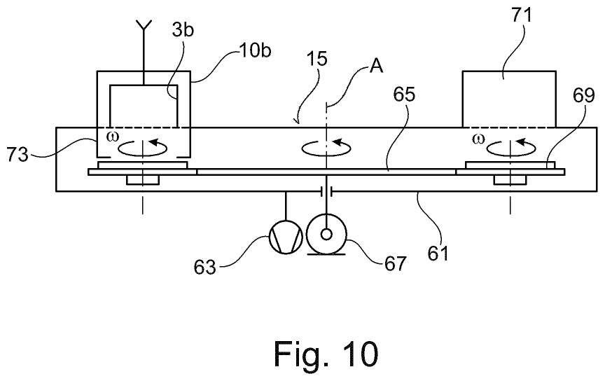

FIG. 10: most schematically and simplified, a further embodiment of the apparatus according to the invention.

FIG. 1 shows most schematically and simplified the generic embodiment of a plasma source 10 according to the present invention and operating the method of producing ions of a gas species according to the present invention.

Within a vacuum enclosure 1 delimiting a vacuum space of the plasma source 10 there is provided a first electrode 3 and a second electrode 5 spaced from the first electrode 3. Via a matchbox 7 a HF generator 8 is operatively connected to the first and second electrodes 3,5 so as to generate a HF plasma PL between the first and second electrodes 3,5 in a reaction space RS. As shown in dash lines, an “auxiliary” electrode 4 may be provided to influence the plasma PL in the reaction space RS. Such auxiliary electrode 4 may be operated by a supply source 4a with supply power of selected characteristics to achieve a desired effect on the plasma PL.

In the embodiment of FIG. 1 the inner surface of the vacuum enclosure or a part thereof may act as a third electrode as well, if operated on an electric potential different from the electric potentials applied to the primary electrodes 3 and 5 and geometrically located so that the plasma may burn along such part of the inner surface of the vacuum enclosure 1.

By means of a gas feed arrangement 9 gas G is fed into the vacuum recipient 1. The gas G fed into the vacuum recipient 1 comprises more than 50% of a gas species e.g. hydrogen, even at least 80%, even at least 95% of the gas species or even consists of the gas species, whereby neglectable amounts of impurity gases may in practice be present. Thus, the predominant part of the gas G fed to the vacuum enclosure 1 is the gas species, in one embodiment hydrogen.

The gas feed arrangement 9 is gas-supplied from a gas tank arrangement 11 which comprises or consists of a gas species tank 11H. In some embodiments the gas feed arrangement 9 may additionally be supplied, to a minor amount, from one or more than one gas tanks 11G containing e.g. one or more than one noble gases e.g. Ar, or even one or more than one reactive gases different from the gas species, as of hydrogen. In other embodiments the gas feed arrangement is supplied predominantly by a noble gas as the gas species, which is the case when applying the plasma source as an etching source. The respective amounts of gases fed into the vacuum recipient 1 may be controlled by means of a valve arrangement 17.

In the application of exploiting hydrogen as the gas species, predominantly hydrogen in the form of hydrogen ions H+, H2+, H3+, of neutral H or H2 and also of negative hydrogen ions generated from neutral H2 as well as electrons, excited hydrogen or hydrogen radicals, all generated in the plasma PL, are output from the vacuum enclosure 1 through a plasma outlet opening arrangement 13 in the wall of the vacuum enclosure 1 so as to be applied to a vacuum treatment apparatus 15 to which the vacuum enclosure 1 of the plasma source 10 is mountable. The reactive species of the gas species from the plasma source allow a reaction on a substrate exposed to the plasma outlet opening arrangement 13 of the plasma source which may include a chemical reaction—as by atomic hydrogen—, influencing stress in a layer on such substrate, influencing surface roughness or surface etching thereby making use of respectively selected predominant gas species.

Although pumping of the vacuum enclosure 1 may be performed by a pumping arrangement connected to the vacuum enclosure 1 itself, as shown in dash line in FIG. 1, pumping also of the vacuum enclosure 1 is performed, in one embodiment of the plasma source 10, by means of a pumping arrangement 19 connected downstream the plasma source 10, namely connected to the vacuum treatment apparatus 15 wherein (not shown) the substrate to be treated is located. Thereby and advantageously a pressure gradient Op may be established across the plasma outlet opening arrangement 13.

Making use of a capacitively coupled HF plasma PL for ionizing the gas species G has the significant advantage over other plasmas e.g. inductively coupled plasmas, exploitable for generating ions in a plasma source, that the plasma potential may be quite easily indirectly monitored, indirectly pre-set and also in situ adjusted, an entity which significantly governs the energy of the ions leaving the plasma outlet opening arrangement 13. This prevails especially for a specific type of capacitively coupled plasma, as will be addressed later.

In a plasma source 10 making use generically of a capacitively coupled HF plasma PL as generically exemplified by the embodiment of FIG. 1 different process parameters may be used to set or even adjust the energy of ions outlet from the plasma outlet opening arrangement 13, as in some embodiments predominantly of hydrogen ions. Such parameters are e.g. frequency and power of the supply signal from HF generator 8, supply of an auxiliary electrode 4. Nevertheless, when considering setability or even in situ adjustability of the addressed energy, one must always consider stability of the resulting plasma as well. Setting or adjusting a desired energy of ions leaving the plasma source 10 by one or more than one of the addressed process parameters may easily result in instability of the plasma and may thus not straight forwards be realized.

In the embodiment of FIG. 2 a special type of generating a capacitively coupled HF plasma is applied which significantly simplifies setting or adjusting the energy of ions of the gas species, in some embodiments predominantly hydrogen ions, generated and leaving the plasma source 10a, thereby maintaining stability of the plasma PL.

According to the embodiment of the plasma source according to the invention as shown in FIG. 2 operating a variant of the method according to the invention, the capacitively coupled HF plasma PL is generated exclusively between a smaller electrode surface including the electrode surface ELS of the first electrode 3a and a larger electrode surface ELS including the electrode surface of the second electrode 3b. No additional electrode surface influences the plasma discharge.

Due to the “only two” electrode surface approach such HF plasma generator is often called a “diode” arrangement. Such diode arrangement of the HF plasma generating electrode surfaces obeys substantially the law of Koenig as e.g. addressed in U.S. Pat. No. 6,248,219. The plasma is in operational contact solely with an electrode surface arrangement which consists of a first electrode surface and of a second electrode surface substantially facing the first electrode surface. As heuristically addressed in FIG. 3 the law of Koenig defines that the ratio of the drop of time averaged electrical potential ΔΦ adjacent to the electrode surfaces ELS between which a HF plasma discharge is generated, is given by the inverse ratio of respective electrode surface areas raised to a power, in praxis, between 2 and 4. The conditions for which the law of Koenig is valid are also addressed in the patent as mentioned. Therefrom results the skilled artisan's knowledge, that the smaller electrode surface exposed to the HF plasma is predominantly etched, the larger being predominantly sputter coated. Please note from FIG. 3 the definitions of “plasma potential” and of “DC self-bias potential”.

According to the embodiment of FIG. 2 the second electrode 3b is cup-shaped and has an electrode surface ELS3b which is larger than the electrode surface ELS3a of the first electrode 3a. The first electrode 3a is realized by a grid the openings thereof being the plasma outlet opening arrangement 13a.

The grid has a transparency of more than 50%, transparency being defined by the ratio of the sum of all opening surfaces to the overall surface of the grid.

The openings of the grid of the first electrode 3a are dimensioned, so that a fraction of the species present in the plasma PL are output therethrough. The first electrode 3a as well as the wall of the vacuum enclosure 1 are operated on the electric potential of a wall 16 of the vacuum treatment apparatus 15 i.e. on ground potential. The spacing d between the inner surface of the wall of the vacuum enclosure 1 and the second electrode 3b is selected so that no plasma may burn therein, i.e. is selected to be smaller than the prevailing dark space distance.

The gas feed arrangement 9 comprises an exterior part 9a which is operated on ground potential. A second part 9b comprising the line arrangement discharging the gas G into the cup-space of the second electrode 3b is electrically isolated from part 9a as schematically shown by isolator 19. To avoid any metallic surface part interacting with the capacitively coupled plasma PL the part 9b of the gas feed line arrangement within the cup space of the second electrode 3b is operated on the HF potential of the second electrode 3b as schematically shown by the electric connection 12.

FIG. 4 shows schematically and simplified an embodiment of the gas feed part 9b of FIG. 2. Thereby the gas feed to the inner space of cup shaped second electrode 3b is realized through gas feed openings 24 in the second electrode 3b. The exterior part 9a of the gas feed arrangement 9 discharges in a distribution space 20 between the rear surface of the second electrode 3b and the inner surface of the wall of the vacuum enclosure 1. As was addressed before, in this space 20 no plasma may burn. The distribution space 20 is additionally confined by an electrically isolating frame 22, e.g. of a ceramic material. Gas G fed to the distribution space 20 is fed into the cup shaped space of the second electrode 3b through a pattern of distributed openings 24.

We have addressed the advantage of operating a plasma source by means of a capacitively coupled HF plasma with respect to setting or even adjusting the energy of ions output from the source, but have also, in this context, addressed that stability of the plasma is to be maintained.

In an embodiment making use of a diode electrode arrangement for generating the plasma and as exemplified by the embodiment of the FIGS. 2 to 4, this may be achieved by mechanically or rather virtually setting or adjusting the ratio of the electrode surfaces. With an eye on FIG. 3 please note that by such setting or adjusting, the potential differences ΔΦs and ΔΦL will both be set or adjusted. Whenever one of ΔΦs and ΔΦL rises, the other potential difference drops. Thus, the plasma potential, essential for the energy of the ions output from the plasma source, is set or adjusted as well. Nevertheless, the plasma potential itself is not easily monitored. But: The DC self-bias potential ΔΦm is uniquely correlated with the plasma potential. Therefore, the DC self-bias potential may be monitored as an entity significant at least for variations of the plasma potential. In the general case, from monitoring the DC self-bias potential one may not directly conclude on the prevailing value of the plasma potential but may at least conclude on the direction of a variation of the plasma potential. This may nevertheless be a most important information, especially if, as will be addressed later, the plasma potential is to be negative feedback controlled.

In that case where the smaller electrode surface ELS3a including the surface of the grid electrode 3a is substantially smaller than the larger electrode surface ELS3b as in embodiments of the plasma source of the present invention according to the FIG. 2 to 4, the course of the DC potential between the smaller and the larger electrode surfaces becomes highly asymmetric. Therefore, ΔΦL becomes small and the DC self-bias potential ΔΦm becomes at least approximately equal to the plasma potential. Thereby the DC self-bias potential ΔΦm becomes directly an entity significant for the prevailing energy of ions output from the plasma source 10a.

For setting or adjusting the plasma potential, the DC self-bias potential ΔΦm and the energy of ions output from the hydrogen plasma source 10a may be performed by mechanically setting or adjusting the ratio of the electrode surfaces ELS3a,3b.

This may be realized e.g. according to the embodiment of FIG. 5, by adding, changing or removing a body 26 in the open space of the cup shaped electrode 3b which body is operated on the same electric potential as the electrode 3b and wherein the surface of that body 26 is exposed to the plasma. Thereby the effective electrode surface of electrode 3b is set or adjusted. We refer with respect to such an approach to the WO2018/121898 of the same applicant as the present invention. Clearly, setting or adjusting the extent of an electrode surface exposed to the plasma may also be realized, instead or additionally to setting or adjusting the electrode surface ELS3b at the second electrode 3b, by enlarging or reducing the electrode surface ELS3a of the first electrode 3a.

By mechanically setting or adjusting at least one of the two electrode surfaces ELS3a,3b, the respective surface ratio and, as a function thereof, the DC self-bias potential and, as a function thereof, the energy of ions leaving the plasma source is set or adjusted.

Mechanically setting or adjusting the ratio of the electrode surfaces ELS of the electrodes 3a and 3b is nevertheless hardly to be realized in situ, i.e. during operation of the plasma source, in some embodiments, of the hydrogen plasma source.

This is nevertheless achieved by a further embodiment directed on setting or adjusting the energy of ions output from the plasma source 10b according to FIG. 6. There is generated in the reaction space RS within the cup-shaped second electrode 3b a confinement magnetic field H for the HF plasma PL by means of a coil arrangement 28. The magnetic field H extends like a tunnel along a part of the electrode surface ELS3b. The one or more than one coils 30 of the coil arrangement 28 are electrically supplied from a supply source arrangement 32, supplying the coil arrangement 28 with one or more than on DC currents I. The coil arrangement 28 is mounted in ambient atmosphere AM outside the vacuum space in the vacuum enclosure 1.

On may say, that the magnetic field H virtually influences the effective electrode surface ELS 3b.

The magnetic field additionally serves for setting or adjusting the lateral distribution of ions extracted from the plasma source through the grid.

By providing in the coil arrangement 28 more than one coils and/or providing at least one of the coils with varying induction effect along the coil axis and/or by supplying more than one coil with different supply DC currents from supply source arrangement 32, the distribution of the magnetic field H in the reaction space RS and along the electrode surface ELS3b may be set or adjusted. By setting or adjusting the magnitude of the magnetic field H also with respect to its distribution along the ELS3b, the energy of the ions leaving the plasma source 10b, in an embodiment of the invention a hydrogen plasma source, may be set or adjusted.

One embodiment of the embodiment of FIG. 6 most suited for setting and adjusting the energy of the ions leaving the plasma source 10b, in some embodiments a hydrogen plasma source, and adapted to additionally maintain plasma stability over a relatively wide range of settable energy of the ions leaving the plasma source is shown in FIG. 7. The coil arrangement 28 comprises at least two distinct coils 30a,30b. The DC current supply source arrangement 32 comprises, according to the number of distinct coils 30 in the coil arrangement 28, at least two DC current supply sources 34a, 34b. At least one of the DC supply currents Ia, Ib may be varied with respect to magnitude and/or or signum, i.e. direction of the respective current. The DC current supply sources are mutually independent. There result magnetic fields Ha and Hb from each of the coils 30 as provided, which magnetic fields Ha and Hb are superimposed to result in the magnetic field H. By setting and adjusting at least one of the absolute magnitudes of the currents Ia, Ib, there common or mutual directional signum, there ratio, the resulting magnetic field H may be set and adjusted so as to achieve a desired energy of the ions leaving the plasma source and maintaining stability of the plasma.

The inventors finding, that the DC self-bias potential may be set or adjusted in a diode type capacitively coupled HF plasma generator device by setting or adjusting a plasma-confinement magnetic field H in the reaction space RS opens the possibility to in situ perform such adjustment and thus also to adjust the DC self-bias potential and the addressed ion energy, by means of a negative feedback control loop. The addressed approach, i.e. negative feed-back controlling the ion energy, may also be realized for ion generating devices different from the plasma source as was addressed till now by different embodiments, e.g. to ion sources more generically or to plasma etching devices, all of diode type.

Please note, that, with an eye e.g. on the plasma source of FIG. 7, an etching device differs therefrom—as perfectly evident to the skilled artisan—only by the fact, that the first electrode 3a is exploited as a carrier for a workpiece to be etched, that different gases, possibly just a noble gas, are fed to the vacuum enclosure 1 which latter is constructed in this case vacuum sealable as a vacuum recipient.

According to all embodiments of the plasma source 10a,10b, in some embodiments of the hydrogen plasma source, as exemplified in the FIGS. 2, 4 to 8 the smaller electrode 3a is operated on ground potential. Thus, at the output of the matchbox 7 there appears the HF supply signal plus a DC-bias which accords with the DC self-bias potential ΔΦm (see FIG. 3).

As was explained above the DC potential at the output of matchbox 7, according to the DC self-bias potential ΔΦm, is significant at least for the rise or drop of the plasma potential and thus of the energy of ions output from the plasma source 10b. If the plasma potential rises, the DC self-bias potential ΔΦm rises as well and vice versa. In the case of a highly asymmetric potential course between the electrode surfaces ELS, the DC self-bias potential becomes practically equal to the plasma potential and is thus a direct indication of the energy of ions output from the plasma source 10b.

According to the embodiment of FIG. 8 the output signal of the matchbox 7a supplying the larger electrode 3b is led over a low pass filter 40 providing a DC output signal according to ΔΦm in FIG. 3. The momentarily prevailing output signal of the low pass filter 40 is compared in a comparing stage 42 with a preset, desired signal value or with a momentarily prevailing value of a desired signal value time-course at an output of a presetting stage 44. The comparison result Δfbc acts via a controller 46, e.g. a proportional/integral controller, on the current source arrangement 32, e.g. adjusting the currents Ia and/or Ib to a e.g. two-coil coil arrangement 28.

In the negative feedback loop as addressed, a signal dependent from the momentarily prevailing DC self-bias potential is sensed, compared with a desired value and the comparing result, as a control deviation signal, adjusts a magnetic field H in the reaction space RS of a diode type plasma generating device, as of the plasma source 10b, according to some embodiments of the present invention a hydrogen plasma source, so that the sensed signal becomes as equal as necessary to the desired, preset value. Please note that the sensed signal may also be compared with a momentarily prevailing value of a desired time course and thus a desired time course of the energy of the ions leaving the plasma source 10b may be established.

The plasma source according to the invention and as described especially in context with the FIGS. 2, 4 to 8 i.e. making use of diode type capacitively coupled HF plasma and, in some embodiments, operated with hydrogen as gas species, is applied to a vacuum treatment apparatus 15 according to the invention, in some embodiments in combination with silicon sputtering, resulting in Si:H layers deposited on a substrate.

Most generically FIG. 9 shows an embodiment of such treatment apparatus 15 according to the invention, schematically and simplified.

A plasma source 10a, 10b as was described and exemplified in context with the FIGS. 2, 4 to 8, especially a plasma source 10b as exemplified with the help of FIGS. 6 to 8 and a silicon sputter source 50 act into a common vacuum space S of a vacuum treatment chamber 52, alternatively or simultaneously. Whereas the plasma source 10b is at least predominantly supplied with the gas species, in some embodiments hydrogen, the sputter source 52—which may be a magnetron sputter source—is at least predominantly supplied with a noble gas, as with argon, thus with more than 50% or with more than 85% or even with more than 95% or the gas supplied to the sputter source 50 even consists of a noble gas, as of argon.

In the vacuum space S of the treatment apparatus 15 a substrate carrier 51 is provided and carries one or more than one substrates 54 facing the plasma source 10b, especially the plasma outlet opening arrangement 13 thereof, and the target of the sputter source 50 which is, in this case, of silicon. The sputter source 50 is electrically supplied (not shown in FIG. 9) and as perfectly known to the skilled artisan with a power characteristic suited for sputtering the respective target material, in this case silicon, e.g. with HF, pulsed DC, HIPIMS. The substrate carrier 51 is drivingly rotatable around a central axis A, as schematically shown by a drive 56.

Astonishingly exposing the sputter-deposited layer as of silicon to ion bombardment, as by hydrogen ions, of desired pre-settable or in situ adjustable energy, as practiced by the plasma source exemplified with the help of FIGS. 6 to 8, it becomes possible to control the stress in the resulting layer as well as surface roughness thereof.

Having recognized this, an additional aspect of the invention became apparent to the inventors:

Applying an ion bombardment by ions of a reactive gas R by means of a diode type plasma source 10b fed with such reactive gas R to be ionized, e.g. with hydrogen as presently has been described but also e.g. with oxygen, to a substrate being sputter coated with a material M allows to control the stress in the deposited layer of MR as well as the surface roughness thereof by controlling the energy of the R-ions generated by the source 10b. This is considered possibly as inventions per se.

FIG. 10 shows schematically and simplified an embodiment of the treatment apparatus 15 as practiced today.

In a vacuum chamber 61, pumped by a pumping arrangement 63, a substrate carrier 65, ring or disks-shaped as represented in the figure, is continuously rotatable around an axis A by means of a drive 67. Substrates 69 are held on the substrate carrier along its periphery and are passed on their rotational path beneath at least one vacuum treatment source 71 e.g. a sputtering source in some embodiments for silicon sputtering and, just subsequently, beneath the plasma sources 10b, shown only schematically in FIG. 10 and constructed as was exemplified with the help of FIGS. 6 to 8. and in some embodiments as addressed combined with silicon sputtering, operated with hydrogen as predominant gas species.

Along the circular conveyance path of the substrates 69 the following sequences of sources may be passed, exemplified by silicon sputter sources and hydrogen plasma sources:
a) At least one sequence of silicon sputter source 71 and subsequently hydrogen plasma source 10b. and/or
b) At least one sequence of silicon sputter source 71 and subsequent hydrogen plasma source 10b and at least one sputter source sputtering a material different from silicon and/or
c) At least one sequence of silicon sputter source 71 and subsequent hydrogen plasma source 10b and at least one sputter source sputtering a material different from silicon and followed by a plasma source for generating reactive gas ions and/or
d) At least one sequence silicon sputter source 71 and subsequent hydrogen plasma source 10b and at least one sputter source sputtering a material different from silicon and followed by a plasma source for reactive gas ions constructed equal to the hydrogen plasma source 10b but gas-supplied with a reactive gas different from hydrogen.
e) At least one sequence of a sputter source for a material different from silicon followed by a plasma source constructed equal to the hydrogen plasma source 10b but gas-supplied with a reactive gas different from hydrogen.
f) At least one sequence of a sputter source for silicon followed by a plasma source constructed equal to the hydrogen plasma source 10b but gas-supplied with a reactive gas different from hydrogen.

The at least one silicon sputtering source 10b is gas supplied (not shown in the fig.) at least predominantly with a noble gas, e.g. argon. In the embodiment practiced today the at least one hydrogen plasma source 10b is gas supplied solely with hydrogen, the at least one silicon sputtering source 71 solely with argon.

The substrates 69 may additionally be rotated around their central axes A69 as shown by ω.

A confinement shield 73 operated on ground potential confines plasma downstream the grid of the smaller electrode 3a. Thereby the smaller electrode surface ELS3a may be adjusted e.g. to reduce etching of that electrode surface.

Per cycle of one silicon sputtering source 71 and of one directly following hydrogen plasma source 10b a Si:H layer is deposited with a thickness D for which there is valid

0.1 nm≤D≤3 nm.

Thereby a substantially homogeneous distribution of hydrogen across the thickness extent of the resulting layer is achieved even when more than one of such cycles are passed by the substrates, one after the other.

By varying the energy of the ions from the hydrogen plasma source 10b when a substrate was silicon sputter-coated and directly subsequently exposed to the hydrogen plasma source 10b, e.g. at the apparatus of FIG. 10, thereby varying such energy by varying the magnetic field H at the source 10b, the stress in the resulting Si:H layer was varied over a range of 500 MPa or even over a range of 800 MPa.

By gas supplying a plasma source according to one of the FIGS. 6 to 8 with hydrogen, thus providing a hydrogen plasma source or with oxygen, thus providing an oxygen plasma source, and by varying the respective ion energies by varying the magnetic field H of the plasma source constructed as exemplified in the FIGS. 6 to 8, surface roughness of the resulting Si:H or, respectively, stress and surface roughness of SiO₂— or, respectively, of HfO₂ layers was largely varied, surface roughness by a factor of at least 10.

Clearly for depositing a HfO₂ layer, hafnium was sputtered.

The fact that the stress as well as surface roughness may be varied and respectively minimized in the resulting layers by adjusting the magnetic field and thereby the DC self-bias potential and thus the energy of ions leaving the plasma source as exemplified in the FIG. 6 to 8 and by bombarding a deposited material layer by such energy ions, is highly advantageous. No deposition process parameter, as e.g. sputter deposition parameter, is thereby to be varied, but solely the magnetic field H of the plasma source constructed according to the plasma source 10b but possibly at least predominantly gas fed with a reactive gas different from hydrogen, e.g. with oxygen.

Summarizing we may say that the methods and apparatus according to the invention especially based on exploiting a HF supplied diode electrode arrangement inventively allow presetting and in situ adjusting the energy of ions leaving the respective plasma source, irrespective of the gas species used according to the needs of respective applications.

1-44. (canceled)

45. A hydrogen plasma source adapted to perform a method of producing ions of a gas species comprising:
feeding a gas comprising more than 50% of a gas species G into a vacuum space;
establishing in said vacuum space an atmosphere of said gas;
establishing in said atmosphere a capacitively coupled HF plasma; and
providing a plasma outlet opening arrangement from said vacuum space.

46. An apparatus with a plasma source according to claim 45 adapted to perform vacuum-process coating of a substrate or of manufacturing a vacuum-process coated substrate comprising operating the method of producing ions of a gas species comprising:
feeding a gas comprising more than 50% of a gas species G into a vacuum space;
establishing in said vacuum space an atmosphere of said gas;
establishing in said atmosphere a capacitively coupled HF plasma; and
providing a plasma outlet opening arrangement from said vacuum space and first-treating said substrate by a process comprising exposing a surface of said substrate to said plasma outlet opening arrangement and second-treating said surface of said substrate, during and/or before and/or after said first-treating, by a vacuum coating process.

47. A plasma source comprising exclusively a first and a second capacitively coupled plasma generating electrode, the first electrode having a larger electrode surface and a second electrode having a smaller electrode surface in a vacuum recipient, a plasma outlet opening arrangement and a gas feed from a gas tank arrangement containing a gas predominantly of a gas species.

48. The plasma source of claim 47 wherein the plasma outlet opening arrangement is through the second electrode.

49. The plasma source of claim 48, wherein said second electrode comprises at least one grid.

50. The plasma source of claim 49 wherein said grid has a transparency of more than 50%.

51. The plasma source of one of claim 47, wherein said second electrode is electrically set on a reference potential.

52. The plasma source of claim 51 wherein said reference potential is ground potential.

53. The plasma source of claim 47 comprising setting one of the two electrodes on a reference potential and comprising a sensing arrangement for the DC bias potential at the other electrode.

54. The plasma source of claim 53 comprising setting the second electrode on said reference potential.

55. The plasma source of claim 47 wherein at least one of the larger and of the smaller electrode surfaces is variable.

56. The plasma source of claim 47 comprising a coil arrangement generating a magnetic field in the space between said first and second electrodes.

57. The plasma source of claim 47 wherein said first electrode is cup shaped, the inner surface thereof facing the second electrode.

58. The plasma source of claim 57 comprising a coil arrangement along the outer surface of said cup shaped first electrode generating a magnetic field with predominant directional component towards or from said second electrode.

59. The plasma source of claim 58 said coil arrangement comprising at least two coils, independently supplied by respective current sources.

60. The plasma source of claim 47 comprising:
The second electrode set on a reference potential, A sensing arrangement with a first output for a signal indicative of the DC bias potential of the first electrode;
A presetting unit with a second output;
A comparing unit with a first input operationally connected to said first output and with a second input operationally connected to said second output and with a third output operationally acting on the plasma potential of a plasma between said first and second electrodes.

61. The plasma source of claim 60 said third output being operationally connected to an electric supply of a coil arrangement generating a magnetic field in a space between said first and said second electrodes.

62. The plasma source of claim 53 comprising a matchbox with an output arrangement supplying said first electrode with a supply signal comprising a HF signal and outputting a DC component of said supply signal indicative of said DC bias potential.

63. The plasma source of claim 47, wherein said gas species is hydrogen.

64. An apparatus for vacuum treating substrates comprising a plasma source according to claim 47 and a further vacuum treatment chamber.

65. The apparatus of claim 64 wherein said treatment chamber is remote from said further vacuum treatment chamber and comprising a substrate conveyer conveying at least one substrate from said plasma source to said further vacuum treatment chamber or inversely.

66. The apparatus of claim 65 wherein said gas species of said plasma source is hydrogen and said further vacuum treatment is sputter deposition of silicon.
